(19) United States
(12) Patent Application Publication
(10) Pub. No.: US 2026/0254138 A1
(43) Pub. Date: Aug. 27, 2026

(54) TEST ACCESS PORT EXPANDER

(71) Applicant: Schweitzer Engineering Laboratories, Inc., Pullman, WA (US)

(72) Inventors: Nathaniel B. Allen, Moscow, ID (US); Lucas Ingham, Pullman, WA (US); Paul Anthony Carmona, Pullman, WA (US); Briggs Harston, Albion, WA (US); Adam Hagengruber, Pullman, WA (US)

(73) Assignee: Schweitzer Engineering Laboratories, Inc., Pullman, WA (US)

(21) Appl. No.: 19/062,242

(22) Filed: Feb. 25, 2025

(51) Int. Cl. H01R 12/52; G01R 31/28; H01R 12/71; H01R 24/64

(52) U.S. Cl. CPC H01R 12/523; G01R 31/2818; H01R 12/716; H01R 24/64

(57) ABSTRACT

An electrical interface device may include a first printed circuit board (PCB) configured to electrically couple one or more electrical contacts to one or more corresponding conductive headers. The electrical interface device may also include a second PCB configured to electrically couple the one or more corresponding conductive headers to one or more corresponding pins of a connector.

### BACKGROUND

This disclosure relates to connections between electrical devices. More particularly, this disclosure relates to interfacing between pins in a first arrangement with pins in a second arrangement.

Connectors, cables, and the like, such as registered jack 45 (RJ45) connectors, may be used to interface with a printed circuit board (PCB) during testing or operation of the PCB. For example, an RJ45 connector may be used to connect a PCB to a computing device to test network communications, debug, or measure the performance of the PCB design. However, connectors used to interface with the PCB may be subject to variations in pitch, yaw, roll, or other flexing during testing, installation, or operation, which may compromise a precise alignment of electrical connections within the connector or at the PCB. Further, interfacing with a PCB may involve numerous connectors, cables, and the like, which may be time-consuming to properly install and monitor. Cables of numerous connectors may become tangled, connectors may become dislodged, and so on, which may complicate a testing process.

### BRIEF DESCRIPTION OF THE DRAWINGS

FIG. 1 is an illustration of an interface device that may electrically couple pins in a first arrangement to pins in a second arrangement, in accordance with an embodiment;

FIG. 2 is an isometric view of the interface device of FIG. 1 shown without a housing for illustrative purposes, in accordance with an embodiment; and

FIG. 3 is a diagram of a layout of a first PCB of the interface device of FIG. 1, including one or more electrical contacts electrically coupled to one or more through-holes via respective circuit traces, in accordance with an embodiment.

### DETAILED DESCRIPTION

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, unless expressly stated otherwise, the term “or” is intended to be inclusive (e.g., logical OR) and not exclusive (e.g., logical XOR). In other words, the phrase “A or B” is intended to mean A, B, or both A and B.

As mentioned, connectors, cables, and the like, such as registered jack 45 (RJ45) connectors, may be used to interface with a printed circuit board (PCB) during testing or operation of the PCB. While referred to herein as a PCB, the techniques herein may additionally or alternatively be performed using a PCB assembly (PCBA) or other circuitry. For example, an RJ45 connector may be used to connect a PCB to a computing device to test network communications, debug, or measure the performance of the PCB design. However, connectors used to interface with the PCB may be subject to variations in pitch, yaw, or other flexing during testing or operation, which may compromise a precise alignment of electrical connections within the connector or at the PCB. Further, interfacing with a PCB may involve numerous connectors, cables, and the like, which may be time-consuming to properly install and monitor. Cables of numerous connectors may become tangled, connectors may become dislodged, and so on, which may complicate a testing process.

As may be appreciated, PCBs may have various arrangements of circuit traces, test contacts, connector pins, and the like. Further, connection between a PCB and connectors used for testing or operation of the PCB may be facilitated by electrical contacts, electrical pads and/or an arrangement of spring-loaded pins (e.g., “pogo pins”). The spring-loaded pins may be arranged in a grid, for example, such that each spring-loaded pin is separated by a distance. The arrangement may carry an Ethernet signal, and it may be desirable to test the PCB by connecting each of the spring-loaded pins to corresponding pins of an RJ45 connector pinout. In some cases, this has involved carefully connecting numerous wires from the arrangement of spring-loaded pins to the pins of the RJ45 connector pinout, which may be time-consuming and/or prone to user error.

Embodiments described herein are directed towards an interface device that electrically couples first conductors in a first arrangement (e.g., an arrangement of spring-loaded pins) to second conductors in a second arrangement of a connector (e.g., an RJ45 connector). The interface device may include a first PCB, and the first PCB may include circuit traces that electrically couple one or more electrical contacts arranged in the first configuration to one or more corresponding headers. The interface device may also include a second PCB, and circuit traces of the second PCB may electrically couple the one or more corresponding headers to one or more pins of a connector arranged in the second configuration. The one or more corresponding headers may physically separate the first PCB and the second PCB and may carry a current and/or signal (e.g., Ethernet signal) from the first PCB to the second PCB.

The interface device may also include an insulating PCB that may be positioned between the second PCB and the connector. The insulating PCB may include pass-throughs for the pins of the connector and may electrically insulate the one or more corresponding headers from the connector. Additionally, the interface device may include a housing (e.g., insulating housing) that protects the first PCB, the second PCB, the third PCB, and/or the one or more corresponding headers from electrical interference, debris, and the like. Further, the housing may include one or more alignment slots that may receive alignment pins to hold the first conductors to the one or more electrical contacts arranged in the first configuration. The housing may also provide structural support to maintain a standoff distance between the first PCB and the second PCB.

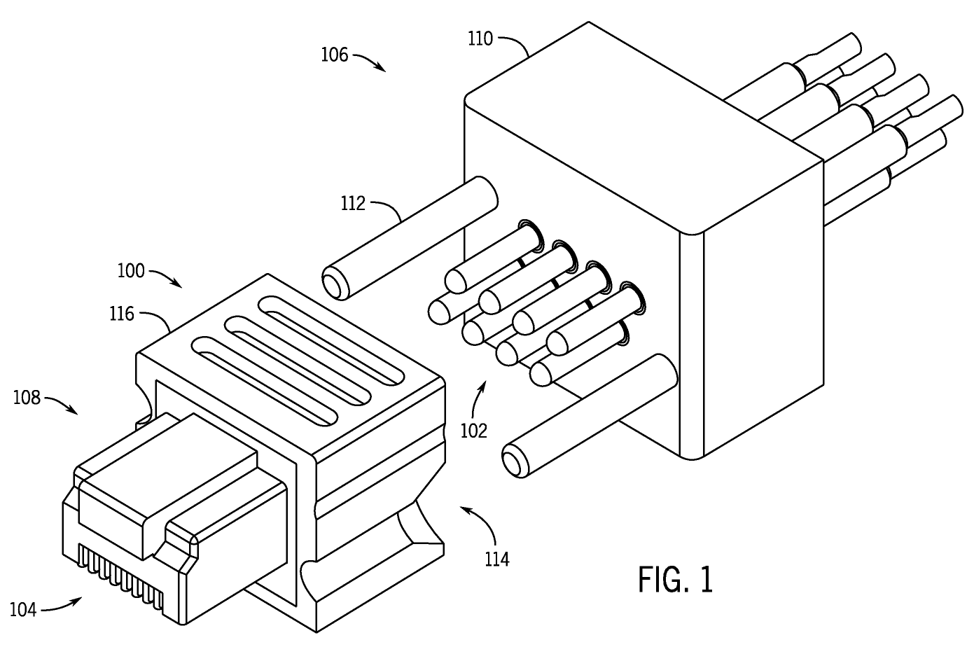

To illustrate, FIG. 1 is an illustration of an interface device 100 that may electrically couple spring-loaded pins 102 in a first arrangement to networking pins 104 in a second arrangement. In the illustrated example, the spring-loaded pins 102 may be included as part of or used in conjunction with a PCB connector 106 that is included as part of, or connected to, a PCB (e.g., a target PCB) or other circuitry. The spring-loaded pins 102 may be arranged in a first arrangement of two rows of four first conductors, as illustrated. Further, the networking pins 104 may be part of a pinout of an RJ45 connector 108, and the RJ45 connector 108 may plug into an RJ45 socket for connection to a computing device, testing apparatus, or the like. It should be noted that, while spring-loaded pins 102 and networking pins 104 are illustrated, the interface device 100 may electrically couple any one or more types of conductors according to various uses or standards, such as a serial communication standard (e.g., RS-232). Additionally or alternatively, in some embodiments, the spring-loaded pins 102 and the networking pins 104 may be arranged in a different arrangement than shown. Further, the connector 108 may have any pinout arrangement and may include any type of connector, such as a d-subminiature connector or terminal block connector.

The spring-loaded pins 102 may be housed by an enclosure 110 that also includes alignment pins 112, and the alignment pins 112 may be inserted into alignment slots 114 of a housing 116 of the interface device 100. The alignment slots 114 may be positioned on the housing 116 such that, when the alignment pins 112 are inserted into the alignment slots 114, the spring-loaded pins 102 contact electrical contacts of the interface device 100 in the first arrangement. Further, the housing 116 may provide structural support to maintain a standoff distance of a first PCB and second PCB that are part of the interface device 100. Further still, the housing 116, including the alignment slots 114, may ease positioning to connect the PCB connector 106 to the interface device 100.

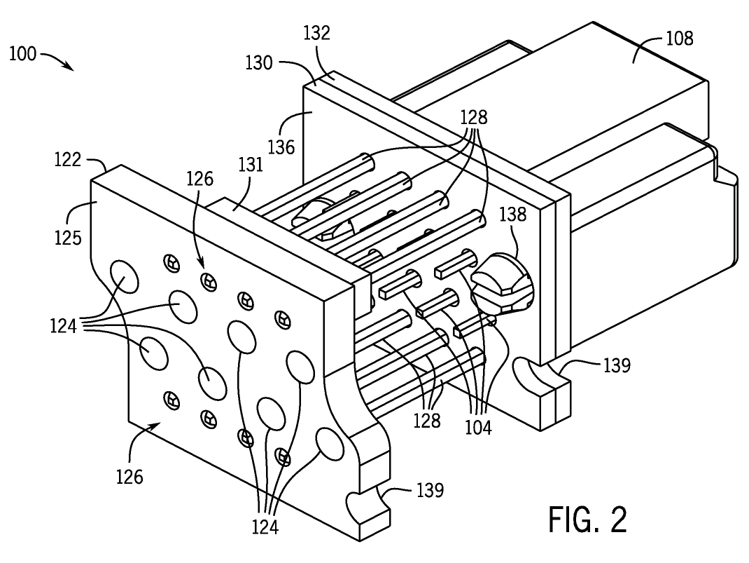

FIG. 2 is an isometric view of the interface device 100, shown without the housing 116 for illustrative purposes. As illustrated, the interface device 100 includes a first PCB 122, also referred to herein as a test pad 122 or test PCB 122, that may couple to spring-loaded pins 102 of FIG. 1. For example, while the first PCB 122 may substantially be made of a substrate, the first PCB 122 may include one or more electrical contacts 124 on a surface 125 facing the outside of the interface device 100. The one or more electrical contacts 124 may have an arrangement that corresponds to an arrangement, for example, of the spring-loaded pins 102. As such, when the spring-loaded pins 102 are coupled to the first PCB 122, each of the spring-loaded pins 102 may contact a respective electrical contact of the one or more electrical contacts 124. The first PCB 122 may be of any suitable thickness, such as between one-sixty-fourth of one inch and one-eighth of an inch (e.g., one-thirty-second of an inch). For example, the thickness of the first PCB 122 may be equal to a thickness of the connector PCB 130 and/or a thickness of the insulating PCB 132. In other examples, the first PCB 122, the connector PCB 130, and/or the insulating PCB 132 may have differing thicknesses.

Additionally, the first PCB 122 may include one or more through-holes 126 (e.g., through-vias, pass-throughs) through which one or more conductive headers 128 may pass through the first PCB 122. Each of the electrical contacts 124 may be electrically coupled to conductive headers 128 via circuit traces disposed within the substrate of the first PCB 122, such that currents, signals, and the like may be carried from the electrical contacts 124, and components coupled thereto, to and from the conductive headers 128. While described as circuit traces, in some examples, electrical coupling may be performed by other suitable circuitry or conductor, such as a conductive pour disposed on the surface of the first PCB 122. Further, the conductive headers 128 may extend beyond the surface 125 of the first PCB 122, such that ends of the conductive headers 128 may be accessed for soldering or testing purposes, such as by probing the ends of the conductive headers 128 with probes of a multimeter, oscilloscope, or the like. The conductive headers 128 may be structurally supported by an insulating spacer 131, as illustrated. For example, the insulating spacer 131 may control the pitch, post height, spacing, and/or alignment of the conductive headers 128. Additionally, the conductive headers 128 and the insulating spacer 131 may together be referred to herein as a header assembly.

The interface device 100 may also include a second PCB 130, also referred to herein as a connector PCB 130, and a third PCB 132, also referred to herein as an insulating PCB 132. As illustrated, the insulating PCB 132 may be disposed between the connector PCB 130 and the connector 108 and may electrically insulate the conductive headers 128 from the surrounding environment, from a jack or port connected to the connector 108, or from a unit under test. For example, the connector PCB 130 may include one or more through-holes through which the conductive headers 128 may pass through at least a portion of the connector PCB 130, and the through-holes may be arranged in alignment with the through-holes 126 of the first PCB 122. However, because the insulating PCB 132 may not have through-holes for the conductive headers 128, the conductive headers 128 may be blocked from extending to contact the connector 108. The insulating PCB 132 may include any insulating material, such as insulating substrate, polycarbonate, thermoplastic resin, or other suitable insulator, and may be of any suitable thickness.

The connector PCB 130 may also include circuit traces (e.g., additional circuit traces) that electrically couple each of the conductive headers 128 to a respective networking pin of the networking pins 104. As mentioned, additionally or alternatively, the conductive headers 128 and the networking pins 104 may be electrically coupled via other suitable techniques, such as a conductive pour on a surface of the connector PCB 130. In the illustrated example, the networking pins 104 of the connector 108 may extend through both the insulating PCB 132 and the connector PCB 130 via respective connector through holes of the insulating PCB 132 and the connector PCB 130. Further, the networking pins 104 may extend beyond a surface 136 of the connector PCB 130 to aid assembly of the interface device 100. This may also allow the networking pins 104 to be accessed for testing purposes, such as by probing the ends of the networking pins 104 with probes of a multimeter, oscilloscope, or the like.

The connector PCB 130 and the insulating PCB 132 may also include fastener holes through which a fastener 138 of the connector 108 may be inserted. The fastener holes of the connector PCB 130 and the insulating PCB 132 may each align with respective fastener holes of the connector 108, allowing the fastener 138 to fasten the connector PCB 130 and the insulating PCB to the connector 108. The fastener 138 may thus provide structural rigidity to the interface device 100. In addition, the first PCB 122, the connector PCB 130, and the insulating PCB 132 may include respective alignment notches 139, and the alignment notches may be used to attach the housing 116 to the first PCB 122, the connector PCB 130, and the insulating PCB 132.

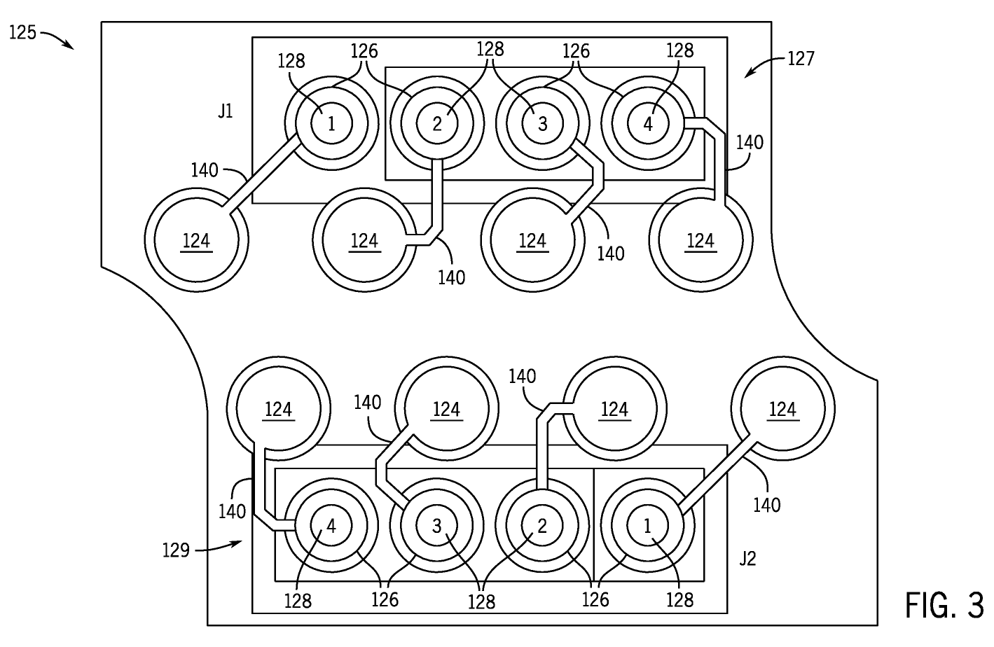

FIG. 3 is an illustration of the surface 125 of the first PCB 122, including the one or more electrical contacts 124, each electrically coupled to a respective through-hole of the one or more through-holes 126 via a respective circuit trace of one or more circuit traces 140. As mentioned, the one or more electrical contacts 124 may have an arrangement that corresponds to an arrangement, for example, of the spring-loaded pins 102 of FIG. 1. As such, when the spring-loaded pins 102 are coupled to the first PCB 122, each of the spring-loaded pins 102 may contact a respective electrical contact of the one or more electrical contacts 124. While FIG. 3 illustrates one arrangement of the one or more electrical contacts 124, the one or more through-holes 126, and the one or more circuit traces 140, other arrangements are envisioned. For example, the one or more electrical contacts 124 may have an arrangement that corresponds to an arrangement of pins of a PCB having a two-by-two arrangement, a one-by-eight configuration, and so on. Further, the first PCB 122 may include any number of the one or more electrical contacts 124, the one or more through-holes 126, and the one or more circuit traces 140.

Each of the one or more through-holes 126 may include a conductive material that electrically couples a respective circuit trace of the one or more circuit traces 140 to a conductive header of the one or more conductive headers 128. As illustrated, the one or more through-holes 126 includes a first subset 127 of the one or more through-holes 126 and a second subset 129 of the one or more through-holes 126 arranged on opposite sides of the one or more contacts of the first PCB 122. As may be appreciated, the first subset 127 of the one or more through-holes 126 may correspond to a first subset of the one or more conductive headers 128, and the second subset 129 of the one or more through-holes 126 may correspond to a second subset of the one or more conductive headers 128

Each of the one or more circuit traces 140 may have a length that is based on aspects of a signal carried by the interface device 100. For example, the one or more circuit traces 140, the one or more conductive headers 128, and the networking pins 104 of the connector 108 may form a path that carries an Ethernet signal between a PCB and a computing device. To properly carry the Ethernet signal, the path may have an appropriate electrical characteristic, such as an impedance, inductance, capacitance, or the like (e.g., to meet timing aspects of the Ethernet signal). As such, the length, shape, route, and so on of the one or more circuit traces 140 may be arranged such that the path achieves the appropriate electrical characteristic. As may be appreciated, the arrangement of the circuit traces 140 may have various forms according to, for example, qualities of a signal or current carried by the interface device 100. Further, while not shown in FIG. 3, the circuit traces of the connector PCB 130 may have similar considerations and characteristics. For example, the circuit traces of the connector PCB 130 that electrically couple each of the conductive headers 128 to respective networking pins of the networking pins 104 may have an appropriate length, shape, route, and so on that is based on aspects of a signal carried by the interface device 100.

While specific embodiments and applications of the disclosure have been illustrated and described, it is to be understood that the disclosure is not limited to the precise configurations and components disclosed herein. Accordingly, many changes may be made to the details of the above-described embodiments without departing from the underlying principles of this disclosure. The scope of the present disclosure should, therefore, be determined only by the following claims.

Indeed, the embodiments set forth in the present disclosure may be susceptible to various modifications and alternative forms, specific embodiments have been shown by way of example in the drawings and have been described in detail herein. However, it may be understood that the disclosure is not intended to be limited to the particular forms disclosed. The disclosure is to cover all modifications, equivalents, and alternatives falling within the spirit and scope of the disclosure as defined by the following appended claims. In addition, the techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]…” or “step for [perform]ing [a function]…”, it is intended that such elements are to be interpreted under 35 U.S.C. 112(f). For any claims containing elements designated in any other manner, however, it is intended that such elements are not to be interpreted under 35 U.S.C. 112(f).

What is claimed is:

1. An electrical interface device comprising:
a first printed circuit board (PCB) configured to electrically couple one or more electrical contacts to one or more corresponding conductive headers; and
a second PCB configured to electrically couple the one or more corresponding conductive headers to one or more corresponding pins of a connector.

2. The electrical interface device of claim 1, comprising a third PCB through which the corresponding pins of the connector couple to the electrical interface device.

3. The electrical interface device of claim 2, wherein the third PCB is configured to electrically insulate the one or more corresponding conductive headers from an environment of the electrical interface device.

4. The electrical interface device of claim 2, wherein the third PCB comprises a first surface coupled to the second PCB and a second surface coupled to the connector.

5. The electrical interface device of claim 1, wherein the one or more electrical contacts are configured to electrically couple to corresponding electrical contacts of a target PCB.

6. The electrical interface device of claim 5, comprising an insulating housing around the first PCB and the second PCB.

7. The electrical interface device of claim 6, wherein the insulating housing comprises one or more alignment slots configured to receive corresponding alignment pins of the target PCB.

8. The electrical interface device of claim 1, wherein the connector comprises a Registered Jack 45 (RJ45) connector.

9. An interface, comprising:
one or more electrical headers configured to electrically couple a test pad PCB and a connector PCB;
the test pad PCB configured to electrically couple an additional PCB to the one or more electrical headers; and
the connector PCB configured to electrically couple the one or more electrical headers to pins of a connector.

10. The interface of claim 9, wherein the one or more electrical headers are configured to separate the test pad PCB from the connector PCB by a distance greater than a first thickness of the test pad PCB and a second thickness of the connector PCB.

11. The interface of claim 9, comprising an insulating PCB coupled to the connector PCB and configured to electrically insulate the one or more electrical headers from the connector.

12. The interface of claim 11, wherein a first thickness of the test pad PCB is equal to a second thickness of the connector PCB, a third thickness of the insulating PCB, or both.

13. The interface of claim 12, wherein the first thickness is between one-sixty-fourth of one inch and one-eighth of one inch.

14. The interface of claim 9, wherein the connector comprises a D-subminiature connector or a terminal block connector.

15. The interface of claim 9, wherein the test pad PCB comprises one or more conductive pads configured to electrically couple one or more pins of the additional PCB to the one or more electrical headers.

16. A device electrically coupling first conductive elements arranged in a first configuration to second conductive elements arranged in a second configuration, comprising:
a first PCB comprising:
one or more contacts in the first configuration;
one or more circuit traces coupling the one or more contacts to one or more header pins arranged in a third configuration; and
a second PCB comprising:
one or more additional circuit traces coupling the one or more header pins arranged in the third configuration to the second conductive elements in the second configuration.

17. The device of claim 16, wherein the first configuration comprises a first row of the first conductive elements and a second row of the first conductive elements, wherein the first row is offset from the second row in a first dimension and a second dimension.

18. The device of claim 16, wherein the second configuration comprises a pin layout of an RJ45 connector.

19. The device of claim 16, wherein the third configuration comprises a first subset of the one or more header pins and a second subset of the one or more headers pins arranged on opposite sides of the one or more contacts of the first PCB.

20. The device of claim 19, wherein one or more header pins extend beyond a surface of the first PCB.
